(19) United States
(12) Patent Application Publication
(10) Pub. No.: US 2006/0017176 A1
(43) Pub. Date: Jan. 26, 2006

(54) Bump ball device and placing method thereof

(76) Inventor: Wan-Kyo Jeong, Yongin-si (KR)

Correspondence Address: CANTOR COLBURN, LLP, 55 GRIFFIN ROAD SOUTH, BLOOMFIELD, CT, 06002, US

(21) Appl. No.: 11/180,799

(22) Filed: Jul. 13, 2005

(30) Foreign Application Priority Data
Jul. 26, 2004 (KR) 2004-58459

(51) Int. Cl. H01L 23/48; H01L 21/44

(52) U.S. Cl. 257/780; 257/786; 438/613

(57) ABSTRACT

The present invention provides a bump ball device and a placing method thereof. The bump ball device having a die on which I/O terminal of a plurality of circuit elements are arranged, includes: a plurality of bonding pads which are electrically connected to the I/O terminals of the circuit elements; and a plurality of test pads which are arranged corresponding to the bonding pads and electrically connected to the bonding pads. Even the test system of the low performance can perform the precise electrical characteristic test, thereby reducing test cost for the electrical characteristic test and manufacturing cost of the bump ball device. Further, since the electrical characteristic test is performed through the additional test pads before forming the bump balls, the manufacturing cost is reduced.

### CROSS-REFERENCE TO RELATED APPLICATION

This application claims the benefit of Korean Patent Application No. 2004-58459, filed Jul. 26, 2004, the contents of which are hereby incorporated herein by reference in their entirety

### BACKGROUND OF THE INVENTION

1. Field of the Invention

The present invention relates to a bump ball device and, more particularly, to a bump ball device that an electrical characteristic test can be performed easily and a placing method thereof.

2. Description of the Related Art

Devices or fabricated products have many I/O terminals for performing function and performance test. The I/O terminals are formed using bump ball or solder balls if it is difficult to be made of lead frames due to so many I/O terminals or if package size should be miniaturized.

The technique for forming the I/O terminals using the bump balls is referred to as “bump ball packaging technique”, and a device packaged by the bump ball packaging technique is referred to as “bump ball device”.

FIG. 1 is a plan view of a conventional bump ball device. The bump ball device comprise a die 1 which is including a plurality of circuit elements (not shown) and arranging I/O terminals of the circuit elements on it in a matrix form, a plurality of bonding pads 2 which are arranged on the I/O terminals and electrically connected to the I/O terminals, and a plurality of bump balls 3 which are arranged on the bonding pads 2 and electrically connected to the bonding pads 2.

The bump ball device of FIG. 1 is placed through the following process.

First, when the die 1 is manufactured, the bonding pads 2 are arranged on the I/O terminals of the circuit elements and electrically connected to the I/O terminals of the circuit elements.

The bump balls 3 having conductivity are produced, i.e., arranged on the bonding pads 2, thereby completing the placing operation of the bump ball device.

As described above, before the packaged bump ball device is provided to users or subjected to other processes, the electrical characteristic test is performed to check whether it has a failure or not. The electrical characteristic test of the bump ball device is performed using a test system or tester.

FIG. 2 is a schematic view of a typical test system.

As shown in FIG. 2, the test system includes a plurality of test (or probe) pins 4 which are arranged to correspond to bump balls 3, have a diameter smaller than the bump balls 3 and contact upper surfaces of the bump balls 3, and a test card 5 which performs the actual electrical characteristic test such that it applies a signal to the bump balls 3 and then analyzes a signal output from the bump ball 3 when the plurality of test (or probe) pins 4 electrically contact the bump balls 3.

As described above, the test (or probe) pins 4 of the test system are arranged to correspond to the bump balls 3 and vertically contact upper surfaces of the bump balls 3.

However, the bump balls 3 of the bump ball device have a circular shape and have a narrow contact area.

If the test (or probe) pins 3 of the test system are not in contact with the bump balls 3 at a correct angle, the test (or probe) pins 4 slide along the side surfaces of the bump balls 3, and thus the test (or probe) pins 4 and the bump balls 3 may get damaged.

Further, when the bump balls 3 are produced, there may be a height difference between the bump balls 3, whereas the test (or probe) pins 4 have uniform height. Thus, the height difference between the bump balls 3 and the test (or probe) pins 4 may generate another damage that may cause finally to overkill good dies.

If there is a height difference between the bump balls 3 and the test (or probe) pins 4, the circuit elements corresponding to the bump balls 3 are normally supplied with or outputs a signal, but since the bump balls 3 are not in contact with the test (or probe) pins 4, the test system determines that the circuit elements corresponding to the bump balls 3 abnormally operate.

In order to resolve the problem of the test system of FIG. 2, a method has been suggested that makes contact surfaces of the test (or probe) pins 4 wide to expand the contact area with the bump balls 3 and couples a spring member to the test (or probe) pin 4, so that the test (or probe) pins 4 and the bump balls 3 stably contact regardless of the height difference therebetween.

However, in order to produce the test system having such test (or probe) pins, higher manufacturing cost and complicated manufacturing process are required.

This increases not only the manufacturing cost of the test system but also the test cost for the bump ball device. Accordingly, the manufacturing cost of the bump ball device is increased.

As another method to minimize the manufacturing cost of the bump ball device, a method has been suggested that performs the electrical characteristic test in the bonding pad before arranging bump balls and produces the bump balls on the bump ball device of the good quality. However, if the test (or probe) pins contact the bonding pads, the bonding pads may get worn away, and thus the bonding pads may unstably contact the bump balls.

For the forgoing reasons, the electrical characteristic test of the bump ball device according to the conventional art should be performed after forming the bump balls.

### SUMMARY OF THE INVENTION

An embodiment of the invention provides a bump ball device which has separate pads for an electrical characteristic test, so that the electrical characteristic test can be precisely performed even with the test system of low performance and a placing method thereof.

Another embodiment of the invention provides a bump ball device that an electrical characteristic test can be performed regardless of whether to form the bump balls or not, thereby minimizing the manufacturing cost and a placing method thereof.

The present invention provides a bump ball device having a die on which I/O terminal of a plurality of circuit elements are arranged, including: a plurality of bonding pads which are electrically connected to the I/O terminals of the circuit elements; and a plurality of test pads which are arranged corresponding to the bonding pads and electrically connected to the bonding pads.

The present invention further provides a placing method of a ball grind array device having a die on which I/O terminal of a plurality of circuit elements are arranged, including: arranging a plurality of bonding pads corresponding to the I/O terminals of the circuit elements; and arranging a plurality of test pads corresponding to the bonding pads and electrically connecting the bonding pads and the test pads corresponding to the bonding pads.

### BRIEF DESCRIPTION OF THE DRAWINGS

The foregoing and other objects, features and advantages of the invention will be apparent from the more particular description of a preferred embodiment of the invention, as illustrated in the accompanying drawing. The drawing is not necessarily to scale, emphasis instead being placed upon illustrating the principles of the invention.

FIG. 1 is a plan view of a conventional bump ball device.

FIG. 2 is a schematic view of a typical test system.

FIG. 3 is a plan view of a bump ball device according to a first embodiment of the present invention.

FIG. 4 is a plan view of a bump ball device according to a second embodiment of the present invention.

FIG. 5 is a plan view of a bump ball device according to a third embodiment of the present invention.

### DETAILED DESCRIPTION OF THE PREFERRED EMBODIMENTS

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. Like numbers refer to like elements throughout the specification.

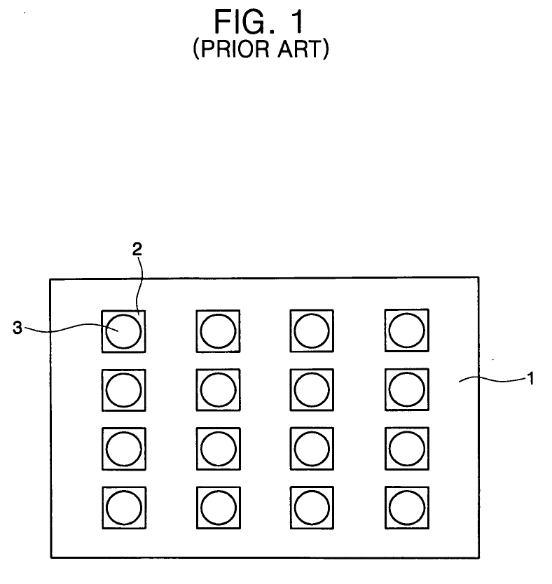

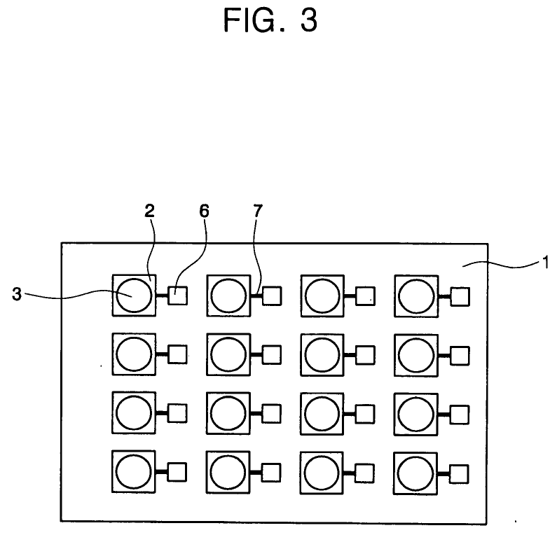

FIG. 3 is a plan view of a bump ball device according to a first embodiment of the present invention. Like reference numerals of FIGS. 1 and 3 denote like parts.

The bump ball device of FIG. 3 comprise a die 1 which is including a plurality of circuit elements (not shown) and arranging I/O terminals of the circuit elements in a matrix form, a plurality of bonding pads 2 which are arranged on the I/O terminals and electrically connected to the I/O terminals, a plurality of bump balls 3 which are arranged on the bonding pads 2 and electrically connected to the bonding pads 2, a plurality of test pads 6 arranged adjacent to the corresponding bonding pads 2, and a plurality of lines 7 for electrically connecting the bonding pads 2 and the test pads 6 corresponding to the bonding pads 2.

Method to place the bump ball device of FIG. 3 is as follows.

First, when the die 1 is manufactured, the bonding pads 2 are arranged to correspond to the I/O terminals of the circuit elements and are electrically connected to the I/O terminals of the circuit elements.

When the arrangement of the bonding pads 2 is completed, the test pads 6 corresponding to the bonding pads 2 are arranged adjacent to the bonding pads 6, and the lines 7 for connecting the bonding pads 2 and the corresponding test pads 6 are arranged.

The bump balls 3 are produced, i.e., arranged on the bonding pads 2, thereby completing the placing operation of the bump ball device.

The test pads 6 of the bump ball device of FIG. 3 are arranged corresponding to the I/O terminals of the circuit elements. That is, the test pads 6 are arranged in the matrix form.

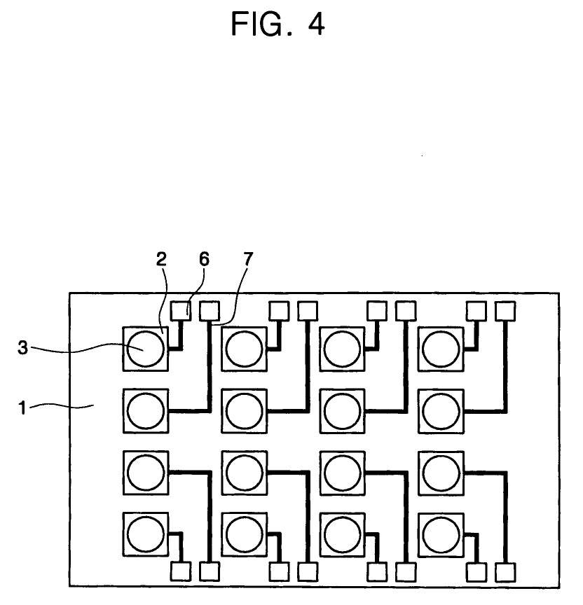

FIG. 4 is a plan view of a bump ball device according to a second embodiment of the present invention. Like reference numerals of FIGS. 3 and 4 denote like parts.

The bump ball device of FIG. 4 comprise a die 1 which is including a plurality of circuit elements (not shown) and arranging I/O terminals of the circuit elements in a matrix form, a plurality of bonding pads 2 which are arranged on the I/O terminals and electrically connected to the I/O terminals, a plurality of bump balls 3 which are arranged on the bonding pads 2 and electrically connected to the bonding pads 2, a plurality of test pads 6 arranged in a row in the edge of the die 1, and a plurality of lines 7 for electrically connecting the bonding pads 2 and the test pads 6 corresponding to the bonding pads 2.

Method to place the bump ball device of FIG. 4 is as follows.

First, when the die 1 is manufactured, the bonding pads 2 are arranged to correspond to the I/O terminals of the circuit elements and are electrically connected to the I/O terminals of the circuit elements.

When the arrangement of the bonding pads 2 is completed, the test pads 6 corresponding to the bonding pads 2 are arranged in a row in the edge of the die 1, and the lines 7 for connecting the bonding pads 2 and the corresponding test pads 6 are arranged.

The bump balls 3 are produced, i.e., arranged on the bonding pads 2, thereby completing the placing operation of the bump ball device.

The test pads 6 of the bump ball device of FIG. 4 are arranged in a row in the edge of the die 1.

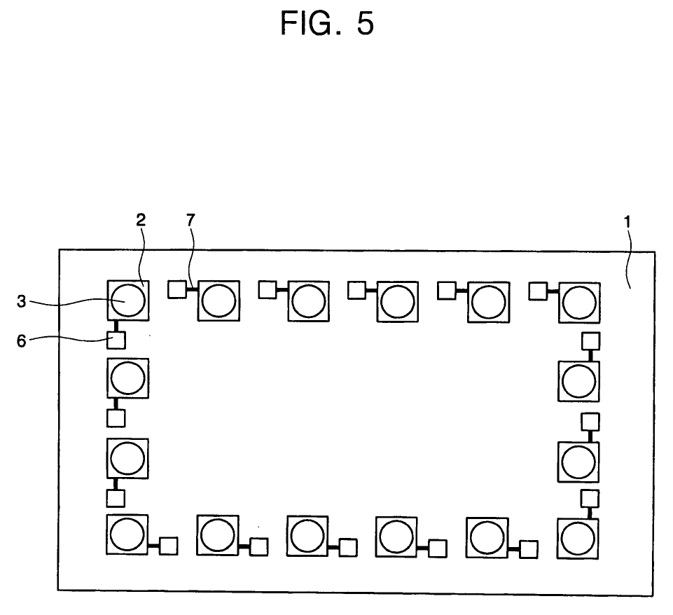

FIG. 5 is a plan view of a bump ball device according to a third embodiment of the present invention. Like reference numerals of FIGS. 3 and 5 denote like parts.

The bump ball device of FIG. 5 comprise a die 1 which is including a plurality of circuit elements (not shown) and arranging I/O terminals of the circuit elements in a row in the edge thereof, a plurality of bonding pads 2 which are arranged on the I/O terminals and electrically connected to the I/O terminals, a plurality of bump balls 3 which are arranged on the bonding pads 2 and electrically connected to the bonding pads 2, a plurality of test pads 6 arranged adjacent to the corresponding bonding pads 2, and a plurality of lines 7 for electrically connecting the bonding pads 2 and the test pads 6 corresponding to the bonding pads 2.

Method to place the bump ball device of FIG. 5 is as follows.

First, when the die 1 is manufactured, the bonding pads 2 are arranged to correspond to the I/O terminals of the circuit elements.

When the arrangement of the bonding pads 2 is completed, the test pads 6 corresponding to the bonding pads 2 are arranged adjacent to the bonding pads 2, and the lines 7 for connecting the bonding pads 2 and the corresponding test pads 6 are arranged.

The bump balls 3 are produced, i.e., arranged on the bonding pads 2, thereby completing the placing operation of the bump ball device.

The test pads 6 of the bump ball device of FIG. 3 are arranged in a row in the edge of the die 1.

As described with reference to FIGS. 3 to 5, the bump ball device has the test pads which have constant height and wide contact area, and the test system can perform the electrical characteristic test of the bump ball device using the test pads.

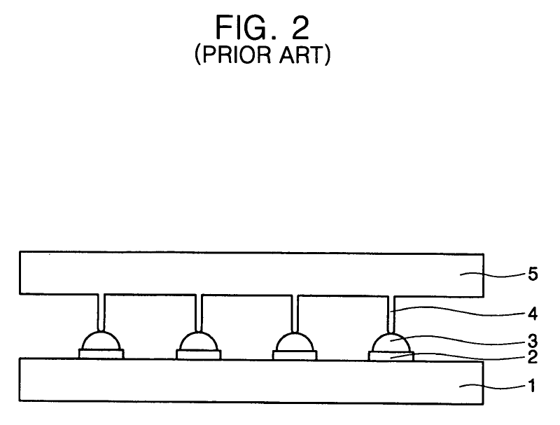

Accordingly, the electrical characteristic test of the bump ball device can be performed by the typical test system of FIG. 2, whereby test cost for the electrical characteristic test and manufacturing cost of the bump ball device can be reduced.

The electrical characteristic test of the bump ball device is performed through the additional test pads, and the bump balls are formed only for the bump ball device of the good quality, thereby reducing the manufacturing cost.

As described herein before, in the bump ball device and the placing method thereof according to the present invention, the test pads which have constant height and wide contact area are arranged and connected to the test system, and the electrical characteristic test is performed. Thus, even the test system of the low performance can perform the precise electrical characteristic test, thereby reducing test cost for the electrical characteristic test and manufacturing cost of the bump ball device.

Further, since the electrical characteristic test is performed through the additional test pads before forming the bump balls, the manufacturing cost may be reduced.

Preferred embodiments of the present invention have been disclosed herein and, although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A bump ball device having a die on which I/O terminal of a plurality of circuit elements are arranged, comprising:
a plurality of bonding pads which are electrically connected to the I/O terminals of the circuit elements; and
a plurality of test pads which are arranged corresponding to the bonding pads and electrically connected to the bonding pads.

2. The device of claim 1, wherein the plurality of test pads are arranged in a row in an edge of the die.

3. The device of claim 1, wherein the plurality of test pads are arranged in a matrix form on the die.

4. The device of claim 1, further comprising a plurality of bump balls formed on upper surfaces of the bonding pads.

5. A placing method of a ball grind array device having a die on which I/O terminal of a plurality of circuit elements are arranged, the method comprising:
arranging a plurality of bonding pads corresponding to the I/O terminals of the circuit elements; and
arranging a plurality of test pads corresponding to the bonding pads and electrically connecting the bonding pads and the test pads corresponding to the bonding pads.

6. The method of claim 5, wherein, in the test pad arranging step, the plurality of test pads are arranged in a matrix form.

7. The method of claim 5, wherein, in the test pad arranging step, the plurality of test pads are arranged in a row in an edge of the die.

8. The method of claim 5, further comprising forming bump balls on upper surfaces of the bonding pads when the arrangement of the bonding pads is completed.
